(19) United States
(12) Patent Application Publication
(10) Pub. No.: US 2013/0141319 A1
(43) Pub. Date: Jun. 6, 2013

(54) Pixel Structure, Array Substrate and Liquid Crystal Display

(71) Applicants: Jinjie Wang, Shenzhen (CN); Pei Jia, Shenzhen (CN)

(72) Inventors: Jinjie Wang, Shenzhen (CN); Pei Jia, Shenzhen (CN)

(21) Appl. No.: 13/376,683

(22) PCT Filed: Dec. 6, 2011
(86) PCT No.: PCT/CN2011/083520

§ 371 Date: Dec. 7, 2011

(30) Foreign Application Priority Data
Dec. 2, 2011 (CN) 2011103961399

(51) Int. Cl. G09G 3/36; H01L 33/08

(52) U.S. Cl. 345/92; 257/59; 257/72; 257/E33.053

(57) ABSTRACT

The present invention relates to a pixel structure, an array substrate and a liquid crystal display. A pixel structure, comprising a plurality of pixel regions, wherein each pixel region comprises a pixel electrode and at least one pair of first thin-film transistor and second thin-film transistor; the first thin-film transistor and the second thin-film transistor in each pair are symmetrically arranged, and the drain electrodes of the first thin-film transistor and the second thin-film transistor are electrically connected with the pixel electrode. Each pixel structure of the liquid crystal display comprises a first thin-film transistor and a second thin-film transistor. Since the first thin-film transistor and the second thin-film transistor are symmetrically arranged, the total parasitic capacitance of each pixel structure would not be changed due to the poor accuracy of an exposure machine and a manufacturing process in actual manufacture. Therefore, the total parasitic capacitance of each pixel structure of the liquid crystal display is constant, thus the poor effect of display due to the deficiency of data lines and thin-film transistors is overcame, and a better effect of display is achieved.

### TECHNICAL FIELD

The present invention relates to the field of liquid crystal display, in particular to a pixel structure, an array substrate and a liquid crystal display.

### BACKGROUND

FIG. 1 is a Layout schematic diagram of an LCD array substrate of the prior art, in the manufacture of the LCD array substrate, the drain electrodes of thin-film transistors at different exposure positions is easy to have deflection relative to the gate electrodes due to the machine and the manufacturing process, therefore the overlap area between the gate electrodes and the drain electrodes of the thin-film transistors at different positions of the substrate would be inconsistent, i. e. different parasitic capacitances Cgd are produced. As shown in FIG. 2, parasitic capacitances Cgd1 and Cgd2 are corresponding to the thin-film transistor 11 and the thin-film transistor 22 respectively in FIG. 1. Due to the poor accuracy of the exposure machine and the manufacturing process, the phenomenon of Cgd≠Cgd2 occurs, making the gray scale between different pixels displayed nonuniform, and further making the LCD have the display deficiency of nonuniform brightness, gleam, etc.

### SUMMARY

In view of the above-mentioned situations, it is necessary to provide a pixel structure, an array substrate and liquid crystal display with good effect of display.

A pixel structure, comprising a plurality of pixel regions; each pixel region comprises a pixel electrode and at least one pair of first thin-film transistor and second thin-film transistor; the first thin-film transistor and the second thin-film transistor in each pair are symmetrically arranged, and the drain electrodes of the first thin-film transistor and the second thin-film transistor are electrically connected with the pixel electrode. The drain electrode and the gate electrode of the first thin-film transistor overlaps each other, and the drain electrode and gate electrode of the second thin-film transistor overlaps each other; the geometry and spacing of the drain electrodes of the first thin-film transistor and the second thin-film transistor are constant. The symmetry arrangement means that the drain electrodes of the two thin-film transistors are on the inner side, and the source electrodes of the two thin-film transistors are on the outer side; or the source electrodes of the two thin-film transistors are on the inner side, and the drain electrodes of the two thin-film transistors are on the outer side. Thus, when the overlap area between the drain electrode and the gate electrode of the first thin-film transistor is reduced or increased, the overlap area between the drain electrode and the gate electrode of the second thin-film transistor will increased or reduced correspondingly to ensure a constant overlap area.

Preferably, the drain electrodes of each pair of said first thin-film transistor and second thin-film transistor are opposite to each other, forming the symmetry arrangement of the first thin-film transistor and the second thin-film transistor. In this case, the drain electrodes of the two thin-film transistors are on the inner side, and the source electrodes of the two thin-film transistors are on the outer side.

Preferably, the source electrodes of each pair of said first thin-film transistor and second thin-film transistor are opposite to each other, forming the symmetry arrangement of the first thin-film transistor and the second thin-film transistor. In this case, the source electrodes of the two thin-film transistors are on the inner side, and the drain electrodes of the two thin-film transistors are on the outer side.

Preferably, each pixel region comprises one pair of first thin-film transistor and second thin-film transistor.

Preferably, each first thin-film transistor and second thin-film transistor are positioned on the same side of the pixel region.

Preferably, each first thin-film transistor and second thin-film transistor are positioned on the cross in the pixel region.

An array substrate, comprising a plurality of data lines and scan lines, wherein the array substrate comprises the pixel structure; each data line comprises a first data line and a second data line; the first data line is connected with the source electrode of the first thin-film transistor of the pixel structure, and the second data line is connected with the source electrode of the second thin-film transistor of the pixel structure; the gate electrodes of the first thin-film transistor and the second thin-film transistor of the pixel structure share one scan line.

A liquid crystal display device, comprising an array substrate.

Each pixel structure of the liquid crystal display comprises a first thin-film transistor and a second thin-film transistor. Since the first thin-film transistor and the second thin-film transistor are symmetrically arranged, the total parasitic capacitance of each pixel structure would not be changed due to the poor accuracy of an exposure machine and a manufacturing process in actual manufacture. Therefore, the total parasitic capacitance of each pixel structure of the liquid crystal display is constant, thus the poor effect of display due to the deficiency of data lines and thin-film transistors is overcame, and a better effect of display is achieved.

### DESCRIPTION OF FIGURES

FIG. 1 is a plan sketch of the array substrate of the prior art;

FIG. 2 is a plan sketch of the parasitic capacitance between the drain electrode and the gate electrode of thin-film transistor in the pixel structure of the prior art shown in FIG. 1;

FIG. 3 is a plan sketch of the preferred embodiment of the array substrate of the present invention;

FIG. 4 is a plan sketch of the parasitic capacitance between the drain electrode and the gate electrode of thin-film transistor of the thin pixel structure shown in FIG. 3.

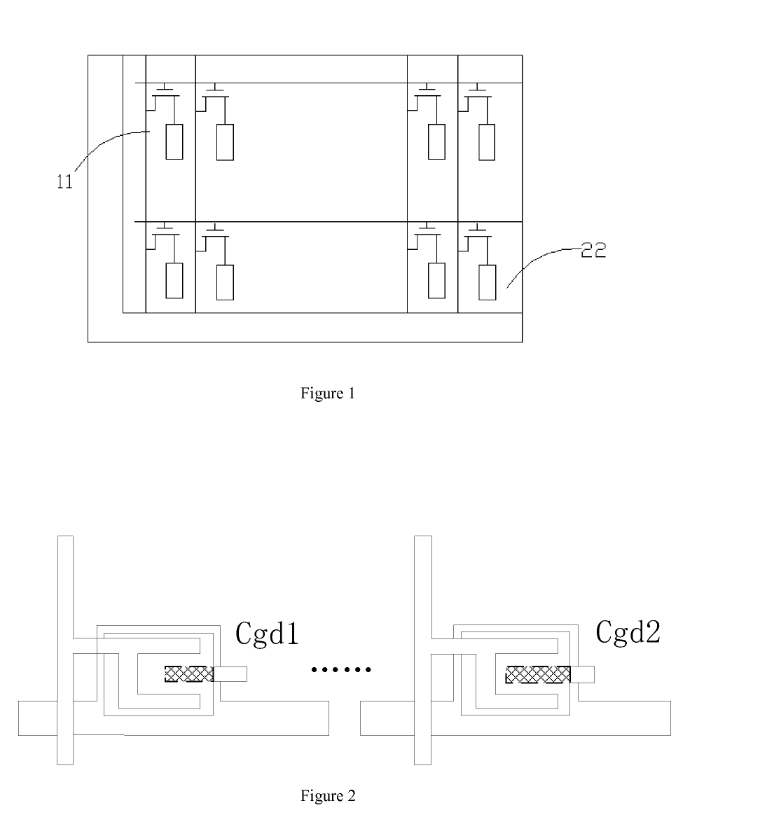

### DETAILED DESCRIPTION

The liquid crystal display of the present invention is further described in detail by figures and embodiments as follows.

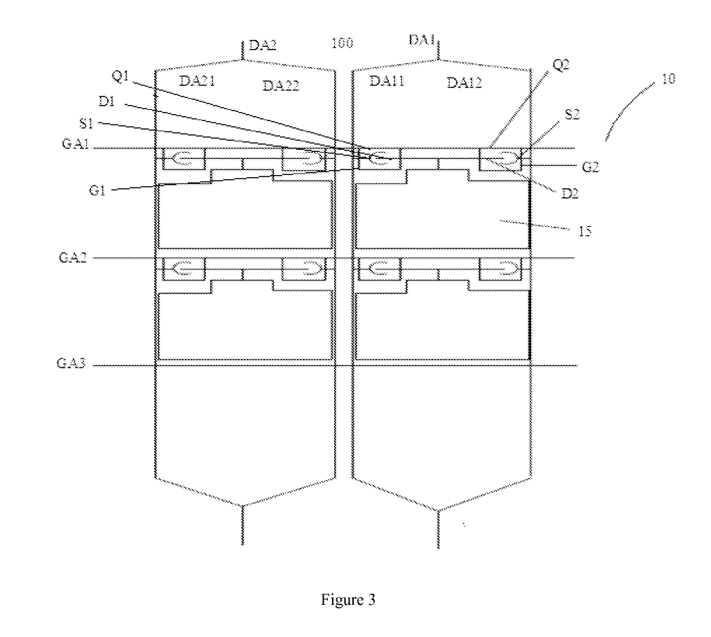

See FIG. 3, a liquid crystal display (TFT-LCD) 100 as shown in the preferred embodiment of the present invention can be an LCD with high resolution and/or high display frequency. The liquid crystal display 100 comprises an array substrate; the array substrate comprises a pixel structure, a plurality of data lines, a plurality of scan lines and a plurality of pixel structures 10; each data line comprises a first data line and a second data line.

The pixel structure comprises a plurality of pixel regions; each pixel region comprises a pixel electrode and at least one pair of first thin-film transistor and second thin-film transistor; the first thin-film transistor and the second thin-film transistor in each pair are symmetrically arranged, and the drain electrodes of the first thin-film transistor and the second thin-film transistor are electrically connected with the pixel electrode. The first data line is connected with the source electrode of the first thin-film transistor of the pixel structure, and the second data line is connected with the source electrode of the second thin-film transistor of the pixel structure; the gate electrodes of the first thin-film transistor and the second thin-film transistor of the pixel structure share one scan line. The symmetry arrangement means that the drain electrodes of the two thin-film transistors are on the inner side, and the source electrodes of the two thin-film transistors are on the outer side; or the source electrodes of the two thin-film transistors are on the inner side, and the drain electrodes of the two thin-film transistors are on the outer side. Thus, when the overlap area between the drain electrode and the gate electrode of the first thin-film transistor is reduced or increased, the overlap area between the drain electrode and the gate electrode of the second thin-film transistor will increased or reduced correspondingly to ensure a constant overlap area.

Particularly, the drain electrodes of each pair of first thin-film transistor and second thin-film transistor are opposite to each other, forming the symmetry arrangement of the first thin-film transistor and the second thin-film transistor. Certainly, the source electrodes of each pair of said first thin-film transistor and second thin-film transistor can be opposite to each other, forming the symmetry arrangement of the first thin-film transistor and the second thin-film transistor.

Each of the first thin-film transistor and the second thin-film transistor are positioned on the same side of the pixel region; or each of the first thin-film transistor and the second thin-film transistor are positioned on the cross in the pixel region.

The drain electrode and the gate electrode of the first thin-film transistor overlaps each other, and the drain electrode and gate electrode of the second thin-film transistor overlaps each other; the geometry and spacing of the drain electrodes of the first thin-film transistor and the second thin-film transistor are constant. The symmetry arrangement ensures that when the overlap area between the drain electrode and the gate electrode of the first thin-film transistor is reduced or increased, the overlap area between the drain electrode and the gate electrode of the second thin-film transistor will increased or reduced correspondingly to ensure a constant overlap area.

Take the embodiment that each pixel region comprises one pair of first thin-film transistor and second thin-film transistor for example to further describe the conception of the present invention. In this embodiment, two data lines are used and marked as DA1 and DA2 respectively; three scan lines are used and marked as GA1, GA2 and GA3 respectively.

Each of the data lines DA1 and DA2 comprises two sub-data lines, i. e. a first data line and a second gate line; the data line DA1 comprises a first data line DA11 and a second data line DA12; data line DA2 comprises a first data line DA21 and a second data line DA22. The sub-data lines DA11 and DA12 are connected outside the A-A region of the two data lines DA1 and DA2 (A-A region refers to the centerline between the two data lines DA1 and DA2). Similarly, the sub-data lines DA21 and DA22 are connected outside the A-A region of the two data lines DA1 and DA2. Thus, even if one of the sub-data lines is broken, a data signal can be automatically repaired by roundabout, so that an electrical signal transferred by the data line DA1 can always be obtained by the pixel structure.

Each pixel structure 10 comprises a pixel electrode 15, a first thin-film transistor Q1 and a second thin-film transistor Q2. The first thin-film transistor Q1 and the second thin-film transistor Q2 are symmetrically arranged in the pixel region; to take account of the numerical aperture of the LCD panel, the sizes of the first thin-film transistor Q1 and the second thin-film transistor Q2 are respectively half of the size of a universal thin-film transistor. Understandably, the specific sizes of the first thin-film transistor Q1 and the second thin-film transistor Q2 can be designed in accordance with the size of the LCD panel, for example, when the pixel structure 10 is applied to an LCD panel with a large size, the sizes of the first thin-film transistor Q1 and the second thin-film transistor Q2 can be enlarged correspondingly.

The concrete structure of the pixel structure 10 is described in detail as follows. The first thin-film transistor Q1 comprises a source electrode S1, a gate electrode G1 and a drain electrode D1; the second thin-film transistor Q2 comprises a source electrode S2, a gate electrode G2 and a drain electrode D2. The source electrode S1 of the first thin-film transistor Q1 is electrically connected with the sub-data line DA11 of the data line DA11; the gate electrode G1 is electrically connected with the scan line GA1; the drain electrode D1 is electrically connected with a pixel electrode 15; and parasitic capacitance Cgd1 is formed between the gate electrode G1 and the drain electrode D1. The source electrode S2 of the second thin-film transistor Q2 is electrically connected with the sub-data line DA12 of the data line DA1; the gate electrode G2 is electrically connected with the scan line GA1, i. e. electrically connected with the gate electrode G1; the drain electrode D2 is electrically connected with the pixel electrode 15; and parasitic capacitance Cgd2 is formed between the grate electrode G2 and the drain electrode D2. The sum of the parasitic capacitance Cgd1 and Cgd2 is the total parasitic capacitance Cgd of the pixel structure 10, i. e. Cgd=Cgd1+Cgd2.

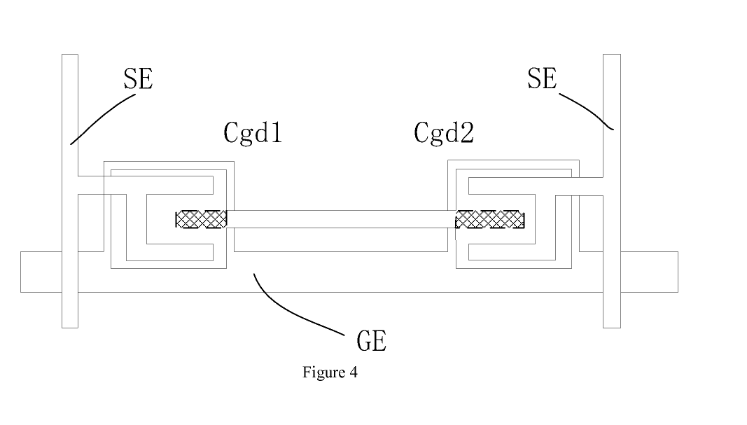

The design principle of the pixel structure 10 is described by FIG. 4 as follows. In theory design phase, the parasitic capacitance Cgd1 is equal to the parasitic capacitance Cgd2. In the actual manufacturing process of an LCD lightproof cover, if a semiconductor electrode layer (SE) has a left deflection relative to a gate electrode layer (GE), the parasitic capacitance Cgd1 will be reduced by X; because the first thin-film transistor Q1 and the second thin-film transistor Q2 are symmetrically arranged, the parasitic capacitance Cgd2 will be correspondingly increased by X; thus the total parasitic capacitance Cgd of the pixel structure 10 will be unchanged, i. e. Cgd=Cgd1−X+Cgd2+X. Similarly, if a semiconductor electrode layer (SE) has a right deflection relative to the gate electrode layer (GE), the parasitic capacitance Cgd1 will be increased by X, and the parasitic capacitance Cgd2 will be correspondingly reduced by X; thus the total parasitic capacitance Cgd of the pixel structure 10 will be unchanged, i. e. Cgd=Cgd1+X+Cgd2−X. Obviously, because the first thin-film transistor Q1 and the second thin-film transistor Q2 are symmetrically arranged, the total parasitic capacitance Cgd of the pixel structure 10 will be unchanged by the poor accuracy of the exposure machine and the manufacturing process even in the manufacture.

Simultaneously, the pixel structure 10 of the present invention comprises a first thin-film transistor Q1 and a second thin-film transistor Q2; the source electrode S1 of the first thin-film transistor Q1 is electrically connected with the sub-data line DA11 of the data line DA1; the source electrode S2 of the second thin-film transistor Q2 is electrically connected with the sub-data line DA12 of the data line DA1; and the sub-data line DA11 and the sub-data line DA12 are connected with each other and share the same data line DA1. Therefore, if either the first thin-film transistor Q1 or the second thin-film transistor Q2 is broken, operation will be maintained by the other thin-film transistor via the signal transferred by the sub-data line DA11 or DA12, so that the pixel structure 10 can work on.

To sum up, each pixel structure 10 of the liquid crystal display 100 of the present invention comprises a first thin-film transistor Q1 and a second thin-film transistor Q2; since the first thin-film transistor Q1 and the second thin-film transistor Q2 are symmetrically arranged, the total parasitic capacitance Cgd of each pixel structure would not be changed due to the poor accuracy of an exposure machine and a manufacturing process in actual manufacture. Therefore, the total parasitic capacitance Cgd of each pixel structure 10 of the liquid crystal display 100 is constant, thus the poor effect of display (such as nonuniform brightness, gleam, etc.) due to the deficiency of data lines and thin-film transistors is overcame, and a better effect of display is achieved.

The above contents are only preferred embodiments of the present invention instead of limitations to the present invention in any form. The present invention is described in detail in accordance with the above contents with the specific preferred embodiments. However, this invention is not limited to the specific embodiments. For the ordinary technical personnel of the technical field of the present invention, on the premise of keeping the technical scheme of the present invention, the technical personnel can make some change or equivalent modification in accordance with the above technical scheme. The actual simple change or equivalent modification made in accordance with the technology of the present invention on the premise of keeping the technical scheme of the present invention should be considered to belong to the scope of the technical scheme of the present invention.

We claim:

1. A pixel structure, comprising: a plurality of pixel regions, each pixel region comprises a pixel electrode and at least one pair of first thin-film transistor and second thin-film transistor; the first thin-film transistor and the second thin-film transistor in each pair are symmetrically arranged, and the drain electrodes of the first thin-film transistor and the second thin-film transistor are electrically connected with the pixel electrode.

2. The pixel structure of claim 1, wherein the drain electrodes of each pair of said first thin-film transistor and second thin-film transistor are opposite to each other, forming the symmetry arrangement of the first thin-film transistor and the second thin-film transistor.

3. The pixel structure of claim 1, wherein the source electrodes of each pair of said first thin-film transistor and second thin-film transistor are opposite to each other, forming the symmetry arrangement of the first thin-film transistor and the second thin-film transistor.

4. The pixel structure of claim 1, wherein each pixel region comprises only one pair of first thin-film transistor and second thin-film transistor.

5. The pixel structure of claim 4, wherein each first thin-film transistor and second thin-film transistor are positioned on the same side of the pixel region.

6. The pixel structure of claim 4, wherein each first thin-film transistor and second thin-film transistor are positioned on the cross in the pixel region.

7. An array substrate, comprising: a plurality of data lines and scan lines, the array substrate also comprises a pixel structure; the pixel structure comprises a plurality of pixel regions, and each pixel region has a pixel electrode; each pixel region comprises at least one pair of first thin-film transistor and second thin-film transistor; the first thin-film transistor and the second thin-film transistor in each pair are symmetrically arranged, and the drain electrodes of the first thin-film transistor and the second thin-film transistor are electrically connected with the pixel electrode; each data line comprises a first data line and a second data line; the first data line is connected with the source electrode of the first thin-film transistor of the pixel structure, and the second data line is connected with the source electrode of the second thin-film transistor of the pixel structure; the gate electrodes of the first thin-film transistor and the second thin-film transistor of the pixel structure share one scan line.

8. The array substrate of claim 7, wherein the drain electrodes of each pair of said first thin-film transistor and second thin-film transistor are opposite to each other, forming the symmetry arrangement of the first thin-film transistor and the second thin-film transistor.

9. The array substrate of claim 7, wherein the source electrodes of each pair of said first thin-film transistor and second thin-film transistor are opposite to each other, forming the symmetry arrangement of the first thin-film transistor and the second thin-film transistor.

10. The array substrate of claim 7, wherein each pixel region comprises only one pair of first thin-film transistor and second thin-film transistor.

11. The array substrate of claim 10, wherein each first thin-film transistor and second thin-film transistor are positioned on the same side of the pixel region.

12. The array substrate of claim 10, wherein each first thin-film transistor and second thin-film transistor are positioned on the cross in the pixel region.

13. A liquid crystal display, comprising: an array substrate, the array substrate comprises a plurality of data lines and scan lines; the array substrate also comprises a pixel structure; the pixel structure comprises a plurality of pixel regions, and each pixel region has a pixel electrode; each pixel region comprises at least one pair of first thin-film transistor and second thin-film transistor; the first thin-film transistor and the second thin-film transistor in each pair are symmetrically arranged, and the drain electrodes of the first thin-film transistor and the second thin-film transistor are electrically connected with the pixel electrode; each data line comprises a first data line and a second data line; the first data line is connected with the source electrode of the first thin-film transistor of the pixel structure, and the second data line is connected with the source electrode of the second thin-film transistor of the pixel structure; the gate electrodes of the first thin-film transistor and the second thin-film transistor of the pixel structure share one scan line.

14. The liquid crystal display of claim 13, wherein the drain electrodes of each pair of said first thin-film transistor and second thin-film transistor are opposite to each other, forming the symmetry arrangement of the first thin-film transistor and the second thin-film transistor.

15. The liquid crystal display of claim 13, wherein the source electrodes of each pair of said first thin-film transistor and second thin-film transistor are opposite to each other, forming the symmetry arrangement of the first thin-film transistor and the second thin-film transistor.

16. The liquid crystal display of claim 13, wherein each pixel region comprises only one pair of first thin-film transistor and second thin-film transistor.

17. The liquid crystal display of claim 16, wherein each first thin-film transistor and second thin-film transistor are positioned on the same side of the pixel region.

18. The liquid crystal display of claim 16, wherein each first thin-film transistor and second thin-film transistor are positioned on the cross in the pixel region.
